(19) United States
(12) Patent Application Publication
(10) Pub. No.: US 2012/0061571 A1
(43) Pub. Date: Mar. 15, 2012

(54) LASER NAVIGATION MODULE

(75) Inventors: Dong Ik SHIN, Gyunggi-do (KR); Ho Chul JOUNG, Gyunggi-do (KR); Bu Whan HYUN, Gyunggi-do (KR); Ki Hoon JANG, Gyunggi-do (KR)

(73) Assignee: SAMSUNG ELECTRO-MECHANICS CO., LTD., Gyunggi-do (KR)

(21) Appl. No.: 12/958,116

(22) Filed: Dec. 1, 2010

(30) Foreign Application Priority Data
Sep. 15, 2010 (KR) 1020100090495

(51) Int. Cl. H01L 31/16; G21K 5/02

(52) U.S. Cl. 250/338.4; 250/504 R

(57) ABSTRACT

Disclosed herein is a laser navigation module. The laser navigation module includes a light source emitting laser light. An IR window allows the laser light emitted by the light source to pass therethrough and be reflected thereon, and prevents the entry of visible light. A housing is equipped with the IR window and includes a transparent or semi-transparent part. An illuminator is provided in the housing to emit light to the outside of the housing. The laser navigation module further includes an opaque part or a blocking layer for selective blocking, thus enabling light to be emitted to a desired area of the housing, therefore making it convenient to use even in a dark place.

### CROSS REFERENCE TO RELATED APPLICATION

This application claims the benefit of Korean Patent Application No. 10-2010-0090495, filed on Sep. 15, 2010, entitled “LASER NAVIGATION MODULE”, which is hereby incorporated by reference in its entirety into this application.

### BACKGROUND OF THE INVENTION

1. Field of the Invention

The present invention relates to a laser navigation module.

2. Description of the Related Art

Generally, a personal mobile communication terminal such as a mobile phone or a smart phone includes a user interface using a keypad. The keypad is provided with input buttons used to input information regarding numerals, characters and directions.

Recently, with the commercialization of wireless internet service such as Wireless Broadband (WIBRO), a personal mobile communication terminal has come to adopt a windows operating system which supports a Graphical User Interface (GUI).

In response to the above-mentioned adoption of the operating system of the GUI for the user interface of the personal mobile communication terminal and the demand for the development of an input device which is suitable for the mobile communication terminal and convenient and easy for a user to use, a touch key, a joy stick and an optical pointing device used to perform sequential input on a keypad displayed on the display screen of the mobile communication terminal has been developed. One such device is a laser navigation module including a window and a lid.

However, the laser navigation module is problematic in that it is not provided with an additional illuminator, so that it is difficult to use the laser navigation module in dark places.

In greater detail, FIG. 1 is an exploded perspective view schematically showing a conventional laser navigation module, which is an input device for a mobile communication terminal. As shown in the drawing, the laser navigation module 100 includes a window 110, a housing 120, a lid 130, a control Integrated Circuit (IC) chip 140, a Printed Circuit Board (PCB) 150, and a dome switch 160.

The window 110 allows laser light emitted by a light source to pass therethrough and be reflected on a user's body, for example, the hand, and blocks the entry of visible light. Further, the window 110 is accommodated in the housing 120.

The lid 130 is positioned below the window 110, serves as a blocking unit for blocking the entry of spill light, and includes a stepped part 131, a circular hole 132, and a rectangular through part 133. The stepped part 131 allows the lid 130 to come into closer contact with the housing 120, the circular hole 132 allows laser light emitted by the light source to pass therethrough, and the rectangular through part 133 allows laser light which is reflected and refracted by a user's body in contact with the window 110 and is then recovered to pass therethrough.

The control IC chip 140 includes a Vertical Cavity Surface Emitting Laser (VCSEL) 141 that is the light source of laser light, functions to calculate the displacement value of the laser light which is reflected and refracted on the window 110 and is then recovered, and is combined with the PCB 150. Further, the dome switch 160 is provided below the PCB 150. The dome switch 160 functions to detect the pressing action of a user and to transmit a user's selection signal to a control unit (not shown) which is located below the dome switch 160.

The conventional laser navigation module is problematic in that it is not provided with an additional illuminator, so that it is inconvenient to use the laser navigation module in a dark place. Further, even though an illuminator may be provided outside the laser navigation module, it is very difficult to install the illuminator in the laser navigation module which is manufactured in a very small size, and it is impossible to uniformly emit light from the internal illuminator to a desired area.

### SUMMARY OF THE INVENTION

The present invention has been made in an effort to provide a laser navigation module, to in which an illuminator is provided in a housing of the laser navigation module, and the housing includes a transparent or semi-transparent part, and an opaque part or a blocking layer for selective blocking, thus enabling light to be emitted to a desired area of the housing, therefore making it convenient to use even in a dark place.

In a laser navigation module according to an embodiment of the present invention, a light source emits laser light. An IR window allows the laser light emitted by the light source to pass therethrough and be reflected thereon, and prevents the entry of visible light. A housing is equipped with the IR window and includes a transparent or semi-transparent part. An illuminator is provided in the housing to emit light to the outside of the housing.

The housing may further include an opaque part for blocking light from going out or coming in, the transparent or semi-transparent part may be provided on an upper portion and a side portion of the housing, and the opaque part may be provided on a lower portion of the housing.

The housing may further include an opaque part for blocking light from going out or coming in, the transparent or semi-transparent part may be provided on an upper portion, a side portion, and a lower portion of the housing, and the opaque part may be provided on an edge of the lower portion of the housing.

The housing may further include an opaque part for blocking light from going out or coming in, the transparent or semi-transparent part may be provided on an upper portion, a side portion, and a lower portion of the housing, and the opaque part may be provided on an edge of the lower portion of the housing.

The housing may further include a blocking layer for blocking light from going out or coming in, the transparent or semi-transparent part may be provided over an entirety of the housing, and the blocking layer may be provided on an outer surface of a side portion of the transparent or semi-transparent part.

The housing may further include a blocking layer for blocking light from going out or coming in, the transparent or semi-transparent part may be provided over an entirety of the housing, and the blocking layer may be provided on outer surfaces of a side portion and a lower portion of the transparent or semi-transparent part.

The housing may further include a blocking layer for blocking light from going out or coming in, the transparent or semi-transparent part may be provided over an entirety of the housing, and the blocking layer may be provided on outer surfaces of a side portion, a lower portion, and a lower edge of the transparent or semi-transparent part other than an upper portion thereof.

The housing may further include a blocking layer for blocking light from going out or coming in, the transparent or semi-transparent part may be provided over an entirety of the housing, and the blocking layer may be provided on an inner surface of the transparent or semi-transparent part other than an upper portion thereof.

The laser navigation module may further include a light diffusion member for emitting the light of the illuminator to the outside. The light diffusion member may include a protrusion which is formed to correspond to the illuminator and change a direction of the light emitted by the illuminator.

The laser navigation module may further include a lid which is positioned below the window, serves as a blocking unit to block entry of spill light, and has a circular hole and a rectangular through part, a control IC chip which has a VCSEL and calculates a displacement value of laser light that is reflected and refracted on the window and is then recovered, a PCB to which the control IC chip is connected, and a dome switch which is provided below the PCB.

The above and other objects, features and advantages of the present invention will be more clearly understood from the following detailed description taken in conjunction with the accompanying drawings.

The terminology or words used in the description and the claims of the present invention should not be interpreted as being limited merely to common or dictionary meanings. On the contrary, they should be interpreted based on the meanings and concepts of the invention in keeping with the scope of the invention on the basis of the principle that the inventor(s) can appropriately define the terms in order to describe the invention in the best way.

### BRIEF DESCRIPTION OF THE DRAWINGS

FIG. 1 is an exploded perspective view schematically showing a conventional laser navigation module;

FIG. 2 is a schematic sectional view showing a laser navigation module according to the present invention;

FIG. 3 is a perspective view schematically showing a housing of a laser navigation module according to a first embodiment of the present invention;

FIG. 4 is a perspective view schematically showing a housing of a laser navigation module according to a second embodiment of the present invention;

FIG. 5 is a perspective view schematically showing a housing of a laser navigation module according to a third embodiment of the present invention;

FIG. 6 is a perspective view schematically showing a housing of a laser navigation module according to a fourth embodiment of the present invention;

FIG. 7 is a perspective view schematically showing a housing of a laser navigation module according to a fifth embodiment of the present invention;

FIG. 8 is a perspective view schematically showing a housing of a laser navigation module according to a sixth embodiment of the present invention; and

FIG. 9 is a perspective view schematically showing a housing of a laser navigation module according to a seventh embodiment of the present invention.

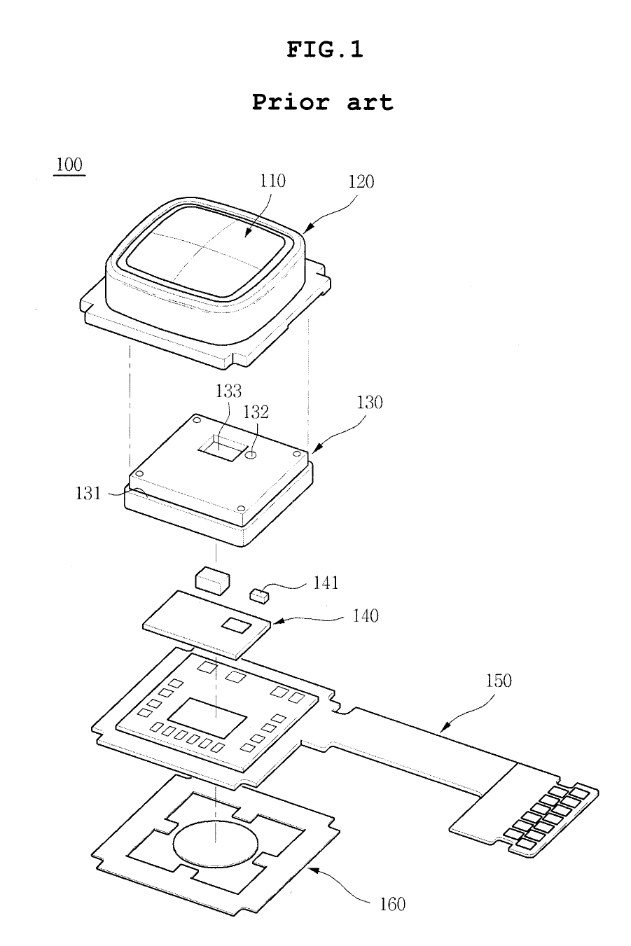

### DESCRIPTION OF THE PREFERRED EMBODIMENTS

The above and other objects, features and advantages of the present invention will be more clearly understood from the following detailed description taken in conjunction with the accompanying drawings. Herein, the same reference numerals are used throughout the different drawings to designate the same components. Terms including “first”, “second”, “one surface”, and “the other surface” may be used to distinguish one component from another component, but the components should not be limited by the terms. Further, when it is determined that the detailed description of the known art related to the present invention may obscure the gist of the present invention, the detailed description will be omitted.

Hereinafter, the preferred embodiments of the present invention will be described in detail with reference to the accompanying drawings.

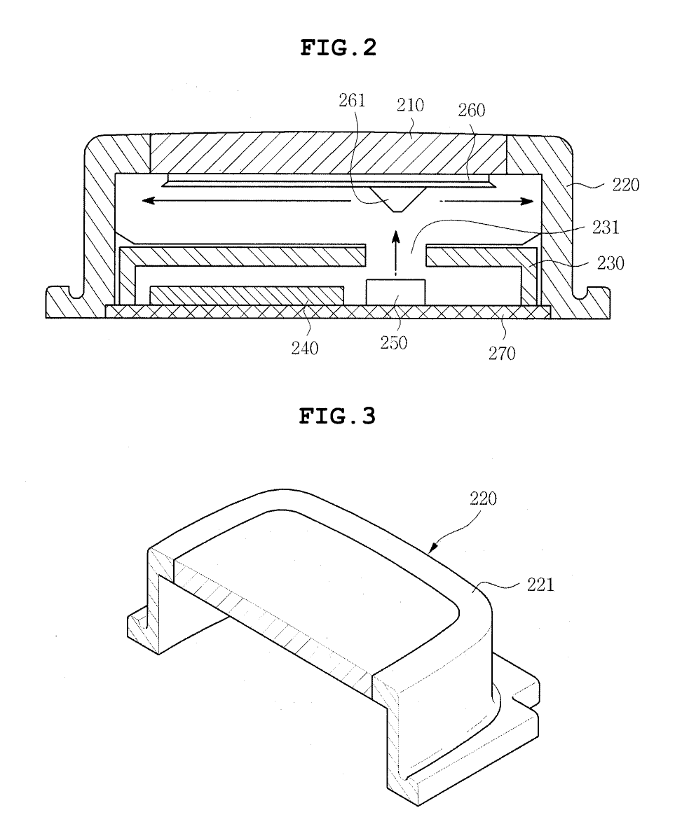

FIG. 2 is a schematic sectional view showing a laser navigation module according to the present invention. As shown in the drawing, the laser navigation module 200 includes an IR window 210, a housing 220, a VCSEL (not shown), a lid 230, a control IC chip 240, an illuminator 250, a light diffusion member 260, a PCB 270 and a dome switch (not shown).

Parts of the laser navigation module according to the present invention are layered in the following order. That is, the PCB 270 is placed above the dome switch (not shown), and the control IC chip 240, the VCSEL (not shown) and the illuminator 250 are mounted on the PCB 270. Further, the lid 230 is provided above the VCSEL and the illuminator 250. Further, the light diffusion member 260 is provided above the lid 230, and the housing 220 equipped with the IR window 210 is coupled to the upper portion of the light diffusion member 260.

In greater detail, the lid 230 is a blocking unit for blocking the entry of spill light, and includes a circular hole (not shown) which allows laser light emitted by the VCSEL that is the light source to pass therethrough, a rectangular through part, and a through hole 231 which allows light emitted by the illuminator 250 to pass therethrough.

The control IC chip 240 includes the VCSEL, and calculates the displacement value of laser light which is reflected and refracted on the IR window 210 and is then recovered. Further, the VCSEL is the light source that emits laser light, and the IR window 210 allows laser light emitted by the VCSEL to pass therethrough and be reflected thereon, and blocks the entry of visible light.

Further, the illuminator 250 functions to emit light to the outside of the housing 220.

The light diffusion member 260 includes a protrusion 261 which changes the direction of light emitted by the illuminator 250 and diffuses the light, and an opening (not shown) through which laser light emitted by the VCSEL pass.

According to an embodiment, the illuminator 250 may comprise an LED.

The housing 220 of the laser navigation module according to the present invention comprises a transparent or semi-transparent member so as to emit light from the illuminator 250 to the outside.

FIG. 3 is a perspective view schematically showing a housing of a laser navigation module according to a first embodiment of the present invention. As shown in the drawing, the entirety of the housing 220 comprises a transparent or semi-transparent part 221, thus allowing light to be emitted to the outside through the entirety of the housing 220.

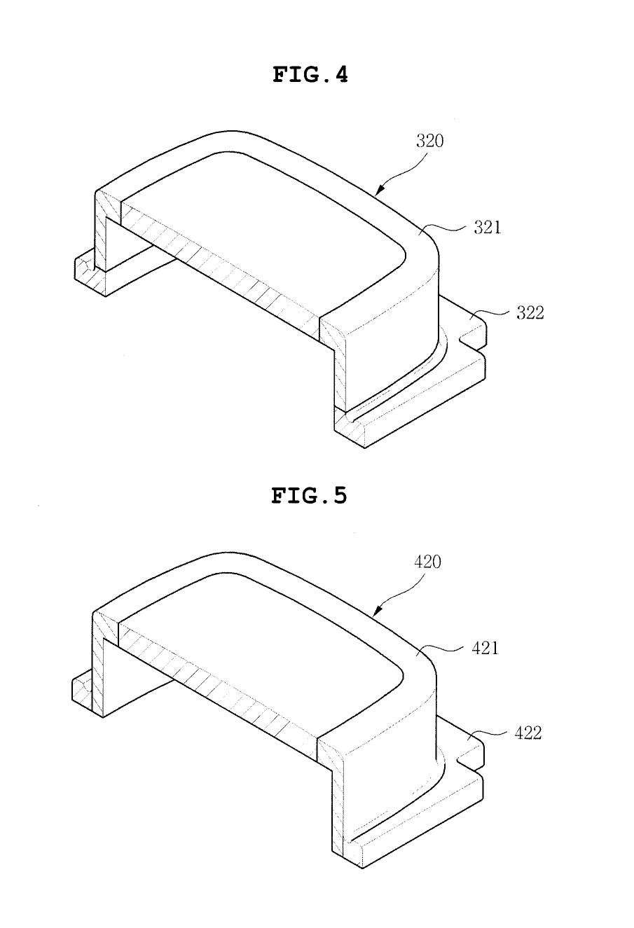

FIG. 4 is a perspective view schematically showing a housing of a laser navigation module according to a second embodiment of the present invention. As shown in the drawing, the housing 320 includes a transparent or semi-transparent part 321 which emits light to the outside, and an opaque part 322 which blocks light from going out or coming in. In greater detail, the transparent or semi-transparent part 321 is provided on the upper and side portions of the housing 320, and the opaque part 322 is provided on the lower portion of the housing 320.

FIG. 5 is a perspective view schematically showing a housing of a laser navigation module according to a third embodiment of the present invention. As shown in the drawing, the housing 420 includes a transparent or semi-transparent part 421 which emits light to the outside, and an opaque part 422 which blocks light from going out or coming in. In greater detail, the transparent or semi-transparent part 421 is provided on the upper, side, and lower portions of the housing 420, and the opaque part 422 is provided on an edge of the lower portion of the housing 320.

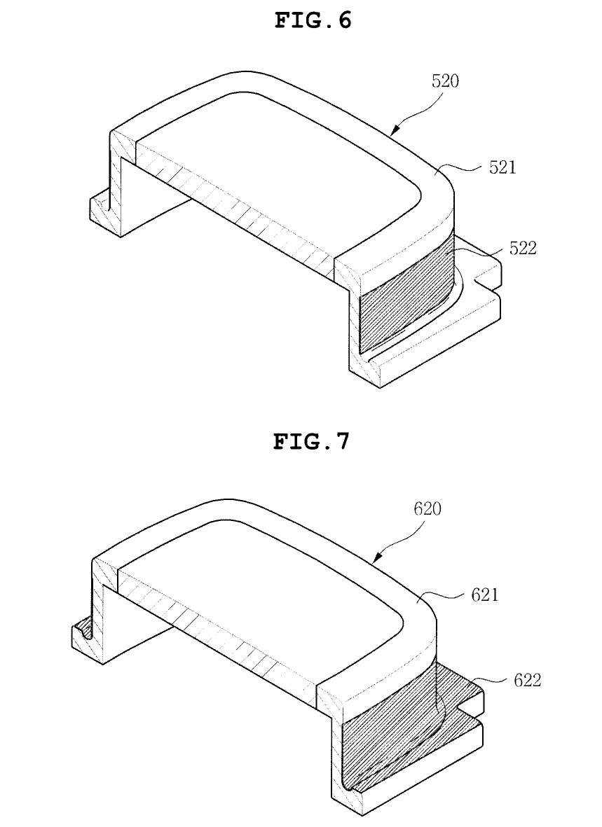

FIG. 6 is a perspective view schematically showing a housing of a laser navigation module according to a fourth embodiment of the present invention. As shown in the drawing, the housing 520 includes a transparent or semi-transparent part 521 which emits light to the outside, and a blocking layer 522 which blocks light from going out or coming in. In greater detail, the transparent or semi-transparent part 521 is provided over the entirety of the housing 520, and the blocking layer 522 is provided on the outer surface of a side portion of the transparent or semi-transparent part 521. Further, the blocking layer 522 may be provided on the housing 520 using various methods, including a coating method and a taping method.

FIG. 7 is a perspective view schematically showing a housing of a laser navigation module according to a fifth embodiment of the present invention. As shown in the drawing, the housing 620 includes a transparent or semi-transparent part 621 which emits light to the outside, and a blocking layer 622 which blocks light from going out or coming in. In greater detail, the transparent or semi-transparent part 621 is provided over the entirety of the housing 620, and the blocking layer 622 is provided on the outer surfaces of a side portion and a lower portion of the transparent or semi-transparent part 621.

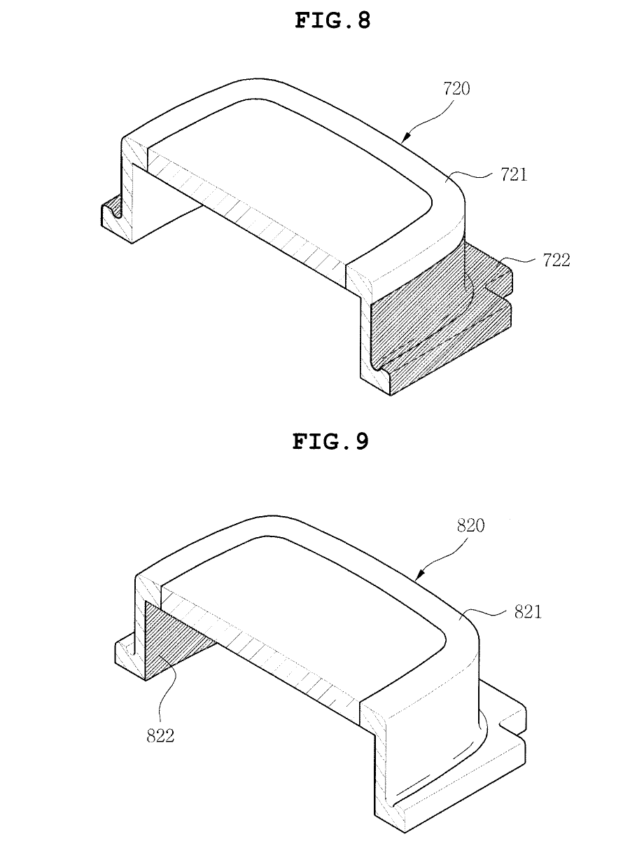

FIG. 8 is a perspective view schematically showing a housing of a laser navigation module according to a sixth embodiment of the present invention. As shown in the drawing, the housing 720 includes a transparent or semi-transparent part 721 which emits light to the outside, and a blocking layer 722 which blocks light from going out or coming in. In greater detail, the transparent or semi-transparent part 721 is provided over the entirety of the housing 720, and the blocking layer 722 is provided on the outer surfaces of the side portion, the lower portion, and the lower edge other than the upper portion of the transparent or semi-transparent part 721. Such a structure allows light of the illuminator 250 to be emitted to the outside through only the upper portion of the housing 720.

FIG. 9 is a perspective view schematically showing a housing of a laser navigation module according to a seventh embodiment of the present invention. As shown in the drawing, the housing 820 includes a transparent or semi-transparent part 821 which emits light to the outside, and a blocking layer 822 which blocks light from going out or coming in. In greater detail, the transparent or semi-transparent part 821 is provided over the entirety of the housing 820, and the blocking layer 822 is provided on the inner surface other than the upper portion of the transparent or semi-transparent part 821. Such a structure allows light of the illuminator 250 to be emitted to the outside through only the upper portion of the housing 820.

As described above, the present invention provides a laser navigation module, in which an illuminator is provided in a housing of the laser navigation module, and the housing includes a transparent or semi-transparent part, and an opaque part or a blocking layer for selective blocking, thus enabling light to be emitted to a desired area of the housing, therefore making it convenient to use even in a dark place.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A laser navigation module, comprising:
a light source emitting laser light;
an IR window allowing the laser light emitted by the light source to pass therethrough and be reflected thereon, and preventing entry of visible light;
a housing equipped with the IR window and including a transparent or semi-transparent part; and
an illuminator provided in the housing to emit light to an outside of the housing.

2. The laser navigation module as set forth in claim 1, wherein the housing further comprises an opaque part for blocking light from going out or coming in, the transparent or semi-transparent part is provided on an upper portion and a side portion of the housing, and the opaque part is provided on a lower portion of the housing.

3. The laser navigation module as set forth in claim 1, wherein the housing further comprises an opaque part for blocking light from going out or coming in, the transparent or semi-transparent part is provided on an upper portion, a side portion, and a lower portion of the housing, and the opaque part is provided on an edge of the lower portion of the housing.

4. The laser navigation module as set forth in claim 1, wherein the housing further comprises a blocking layer for blocking light from going out or coming in, the transparent or semi-transparent part is provided over an entirety of the housing, and the blocking layer is provided on an outer surface of a side portion of the transparent or semi-transparent part.

5. The laser navigation module as set forth in claim 1, wherein the housing further comprises a blocking layer for blocking light from going out or coming in, the transparent or semi-transparent part is provided over an entirety of the housing, and the blocking layer is provided on outer surfaces of a side portion and a lower portion of the transparent or semi-transparent part.

6. The laser navigation module as set forth in claim 1, wherein the housing further comprises a blocking layer for blocking light from going out or coming in, the transparent or semi-transparent part is provided over an entirety of the housing, and the blocking layer is provided on outer surfaces of a side portion, a lower portion, and a lower edge of the transparent or semi-transparent part other than an upper portion thereof.

7. The laser navigation module as set forth in claim 1, wherein the housing further comprises a blocking layer for blocking light from going out or coming in, the transparent or semi-transparent part is provided over an entirety of the housing, and the blocking layer is provided on an inner surface of the transparent or semi-transparent part other than an upper portion thereof.

8. The laser navigation module as set forth in claim 1, further comprising:
a light diffusion member for emitting the light of the illuminator to the outside,
wherein the light diffusion member comprises a protrusion, the protrusion being formed to correspond to the illuminator and change a direction of the light emitted by the illuminator.

10. The laser navigation module as set forth in claim 1, further comprising:
a lid positioned below the window, serving as a blocking unit to block entry of spill light, and including a circular hole and a rectangular through part;
a control IC chip including a VCSEL and calculating a displacement value of laser light which is reflected and refracted on the window and is then recovered;
a PCB to which the control IC chip is connected; and
a dome switch provided below the PCB.
